(19) United States
(12) Patent Application Publication
(10) Pub. No.: US 2007/0063324 A1
(43) Pub. Date: Mar. 22, 2007

(54) Structure and method for reducing warp of substrate

(75) Inventors: Kinuko Mishiro, Kawasaki (JP); Ken-ichiro Tsubone, Kawasaki (JP)

Correspondence Address: ARENT FOX PLLC, 1050 CONNECTICUT AVENUE, N.W., SUITE 400, WASHINGTON, DC, 20036, US

(73) Assignee: Fujitsu Limited

(21) Appl. No.: 11/319,656

(22) Filed: Dec. 29, 2005

(30) Foreign Application Priority Data
Sep. 22, 2005 (JP) 2005-276640

(51) Int. Cl. H01L 23/02

(52) U.S. Cl. 257/678

(57) ABSTRACT

A warp reducing member is bonded to an area on one surface of the substrate corresponding to other side of an electronic part for which the warp is to be reduced with respect to a substrate. An external size of the warp reducing member is substantially same as a size of each of a plurality of electronic parts or large enough to include multiple electronic parts. The warp reducing member is bonded to the substrate with a bonding material having a melting point lower than that of other bonding material that electrically connects the electronic parts to the substrate.

### BACKGROUND OF THE INVENTION

1. Field of the Invention

The present invention relates to a technology for realizing an excellent soldering and assuring a high-density packaging with a high reliability by reducing a warp of a substrate when soldering an electronic part on the substrate.

2. Description of the Related Art

Although there are various types of semiconductor packages available, an attention has been paid recently to a ball-grid-array (BGA) package and a land-grid-array (LGA) package of a surface mount type. With the BGA and the LGA packages, more pins are used, a size becomes larger, and a lead-free solder is employed, and as a result, a soldering temperature has been considerably increased. Consequently, the increased soldering temperature tends to cause a failure of the soldering due to a warp of a mounted part and the substrate, such as a bridge (short circuited) and an open (open circuited), frequently.

In particular, in a mobile apparatus such as a mobile phone, the substrate is becoming thinner to achieve a reduction in size and weight, causing the substrate to warp easily. In addition, for some parts used on the substrate, a size becomes larger to implement an advanced function, and for other parts, a compactness of the parts is accelerated in parallel. As a result, a difference of a thermal capacity becomes large between the parts mounted on the substrate, which causes a large difference in a thermal distribution on the substrate during soldering. This becomes a factor that makes the warp of the substrate even larger.

For example, when a warp is generated between a part and the substrate in mutually opposite directions at 220° C. at which Sn-3.0Ag-0.5Cu solder is melted, a compression force is generated at a soldered portion where the part is brought into contact with the substrate. As a result, the bridge is created on the soldered portion. At another portion where the part is separated from the substrate, the open is created because the solder paste supplied to the substrate cannot make a contact with the part.

An amount of warp of the substrate that causes the above problems can be estimated to be equivalent to a height of the solder paste supplied to the substrate. For example, when the solder paste is supplied to the substrate with a height of 100 μm, a maximum possible amount of warp can be estimated to be about 100 μm.

To solve the above problems, improvements have been made on both the part and the substrate. For the part, for example, a sealant having a coefficient of linear expansion that matches that of an interposer on which a Si chip is mounted has been developed with an improved curing process. Consequently, the amount of warp of the part has been reduced down to approximately 40 μm or less when a 12 mm square BGA package is used.

Furthermore, a real-chip-size package has become widespread, and a structure using the Si chip as a main part has been increased, which also helps reduce the warp. However, as the part becomes larger to implement the advanced function with a combination of various functions, the warp is still becoming larger.

For the substrate, for example, the amount of warp is reduced by improving materials and making wiring (copper foil) densities on the front and back of the substrate uniform. However, even when the materials and wiring densities are controlled, the substrate still shows the warp easily. If too much focus is placed on the wiring density, electrical characteristics of the substrate may be degraded (the ground layer becomes insufficient, for example). Another possible problem is the difficulty of routing wires. The overall result of taking the countermeasures against the substrate warp is highly likely to be disadvantageous. It is also difficult to predict how the substrate warp and the part warp during the heating for soldering.

Particularly, the substrate used in the mobile phone is becoming increasingly thin (0.8 mm thick or less, for example), which causes the substrate further likely to warp. For example, even within a 12 mm square area on a substrate, a warp of about 100 μm may be generated.

For example, as shown in FIG. 15, when a part 2 is mounted on a warped portion of a substrate 1, a defect such as an open 13 occurs at a solder joint 4. If it is difficult to locate visually the defect from an apparent condition, as in the case of the BGA package, there is a possibility of occurrence of a considerable amount of manufacturing defects. As a result, a product quality may be degraded due to an outflow of defective products.

One of the conventional technologies to solve the above problems is disclosed in Japanese Patent Application-Laid-Open No. 2001-320145. As shown in FIG. 16, a stiffener 15 is bonded to the back of the substrate 1 on which the part 2 is mounted using a thermosetting resin sheet 14. The stiffener 15 has a size approximately the same as that of the part 2. The warp in the area on the substrate 1 corresponding to the part 2 is thus reduced.

Another conventional technology is disclosed in Japanese Patent Application-Laid-Open No. 6-204654. In this technology, a frame-like reinforcing plate is mounted on the back surface of the substrate after a part has been mounted on the front surface of the substrate, increasing the reliability after the part mounting.

However, the conventional technology disclosed in Japanese Patent Application-Laid-Open No. 2001-320145, another parts cannot be mounted in the area on the back surface of the substrate 1 to which the stiffener 15 is bonded, which hinders a high-density packaging.

Another problem is that after the part 2 has been mounted, the stiffener 15 cannot be removed easily from the substrate 1 because the thermosetting resin sheet 14 has already been cured. For this reason, the stiffener 15 prevents the entire substrate 1 from being made compact.

In the conventional technology disclosed in Japanese Patent Application-Laid-Open No. 6-204654, the reinforcing plate is mounted after the part is mounted on the front surface of the substrate. Therefore, it is not possible to reduce the warp of the substrate.

### SUMMARY OF THE INVENTION

It is an object of the present invention to at least solve the problems in the conventional technology.

A structure for reducing a warp of a substrate, according to one aspect of the present invention, includes a warp reducing member configured to be bonded to an area on one surface of the substrate corresponding to other side of an electronic part for which the warp is to be reduced with respect to the substrate. An external size of the warp reducing member is substantially same as a size of each of a plurality of electronic parts or large enough to include multiple electronic parts. The warp reducing member is bonded to the substrate with a bonding material having a melting point lower than that of other bonding material that electrically connects the electronic parts to the substrate.

A method of reducing a warp of a substrate, according to another aspect of the present invention, includes bonding a warp reducing member to an area on one surface of the substrate corresponding to other side of a first electronic part for which the warp is to be reduced with respect to the substrate; and mounting the first electronic part on other surface of the substrate corresponding to the area on which the warp reducing member is bonded. The bonding is performed at a same process as mounting a second electronic part on the substrate.

A wiring board according to still another aspect of the present invention includes an electronic part that is mounted in a first area on a first surface of the wiring board with a first bonding material; and a warp reducing member that is bonded to a second area on a second surface of the wiring board with a second bonding material. The second area is corresponding to the first area.

A wiring board according to still another aspect of the present invention includes an electronic part that is mounted on a first surface of the wiring board with a first bonding material; and a warp reducing member that is temporarily bonded on a second surface of the wiring board with a second bonding material.

A method of manufacturing a wiring board, according to still another aspect of the present invention, includes mounting an electronic part on a first surface of the wiring board with a first bonding material; and bonding a warp reducing member to a second surface of the wiring board with a second bonding material.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a cross section of a structure for reducing a warp of a substrate, according to a first embodiment of the present invention;

FIG. 2 is a plan view of the structure for reducing a warp of a substrate;

FIG. 3 is a cross section of a warp reducing member;

FIG. 4 is a cross section of the substrate for illustrating a process for supplying solder paste to the back of the substrate;

FIG. 5 is a cross section of the substrate for illustrating a process for soldering other parts to the back surface of the substrate;

FIG. 6 is a cross section of the substrate for illustrating another process for supplying solder paste to the back of the substrate;

FIG. 7 is a cross section of the substrate for illustrating another process for soldering other parts to the back surface of the substrate;

FIG. 8 is a plan view of a structure for reducing a warp of a substrate, according to a second embodiment of the present invention;

FIG. 9 is a cross section of a substrate warp reducing structure according to a third embodiment of the present invention;

FIG. 10 is a plan view of a warp reducing member according to a fourth embodiment of the present invention;

FIG. 11 is a plan view of a warp reducing member according to a fifth embodiment of the present invention;

FIG. 12 is a cross section of the substrate for illustrating a process for removing a warp reducing member, according to a sixth embodiment of the present invention;

FIG. 13 is a cross section of the substrate for illustrating a process for removing a warp reducing member;

FIG. 14 is a cross section of the substrate for illustrating a process for leveling the solder;

FIG. 15 is a cross section of a substrate for illustrating a conventional part mounting structure; and

FIG. 16 is a cross section of a conventional structure for reducing a warp of a substrate.

### DETAILED DESCRIPTION OF THE PREFERRED EMBODIMENTS

Exemplary embodiments of the present invention will be described below in detail with reference to the accompanying drawings. It should be noted that the present invention is not limited by the embodiments.

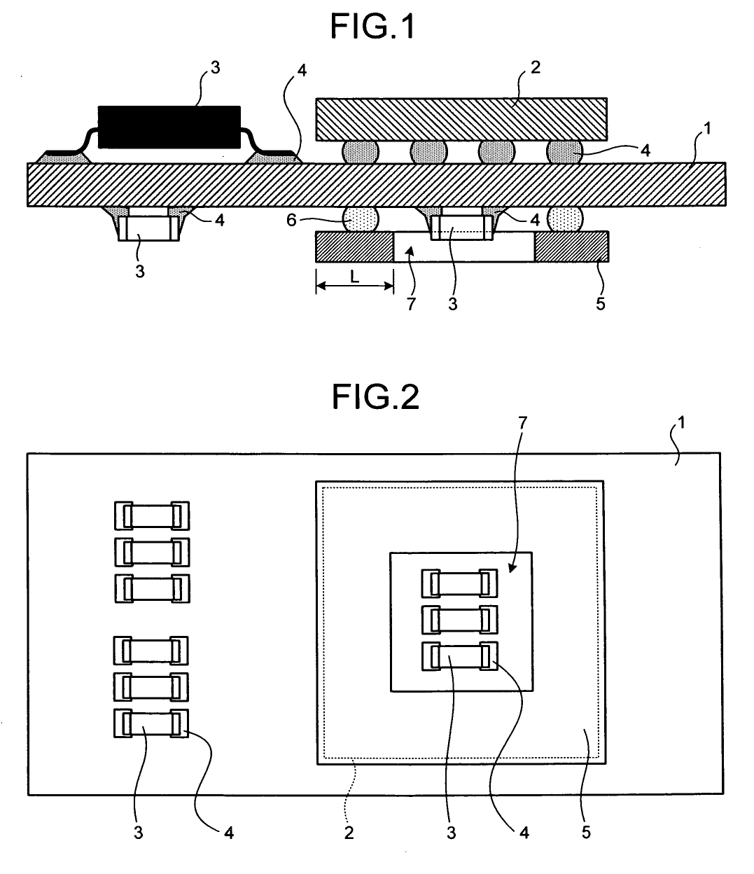

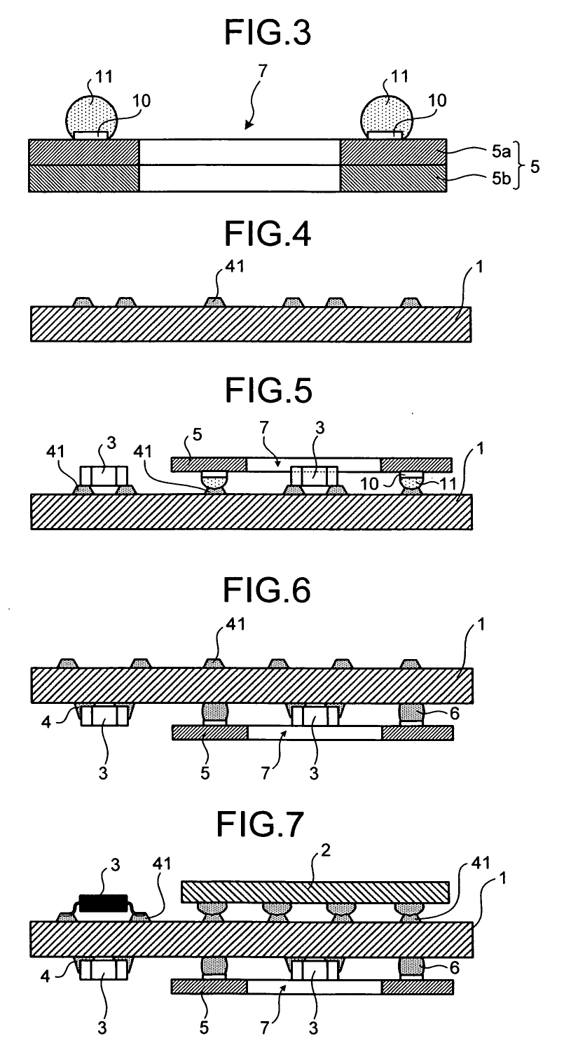

FIG. 1 is a cross section of a structure for reducing a warp of a substrate, according to a first embodiment of the present invention. FIG. 2 is a plan view of the structure for reducing a warp of a substrate. F FIG. 3 is a cross section of a warp reducing member. In the following description, the same reference numerals are assigned to members that are the same as or equivalent to already-described members, and the description for those members will be omitted or simplified.

As shown in FIGS. 1 and 2, an electronic part 2 (hereinafter, “part 2”, indicating a BGA package as an example), for which a warp of the substrate 1 is to be reduced, and other electronic parts 3 (hereinafter, “other parts 3”) are mounted on the substrate 1 using a solder joint 4.

To reduce the warp of the mounting area of the part 2 on the substrate 1, a warp reducing member 5 is bonded to the back of the substrate 1 using a bonding material 6 at a place corresponding to the other side of the part 2 with respect to the substrate 1. The external size of the warp reducing member 5 is equal to or larger than that of the part 2. The warp reducing member 5 includes an opening 7 to eliminate interference with the other parts 3. The warp reducing member 5 has almost the same coefficient of thermal expansion as that of the part 2.

If the other parts 3 are not mounted in the positions on the substrate 1 shown in FIGS. 1 and 2, the warp reducing member 5 does not necessarily include the opening 7. The other parts 3 can be mounted in the area of the opening 7 at the same process as the bonding of the warp reducing member 5.

As shown in FIG. 3, the size of the opening 7 formed in the warp reducing member 5 is not limited to a specific criterion. Because the warp reducing member 5 according to the first embodiment is attached to the substrate 1 by soldering, an electrode 10 required for soldering is formed. Therefore, the size of the opening 7 of the warp reducing member 5 is sufficient if a space for the electrodes 10 is secured on the warp reducing member 5.

Because it is possible to form the warp reducing member 5 with constituent materials equivalent to those of an ordinary BGA package, the warp reducing member 5 can be formed with a substrate 5a and a sealing resin member 5b. The electrode 10 for a solder ball 11 is provided on the substrate 5a.

A glass epoxy substrate with a thickness of about 0.1 mm to 1 mm or a polyimide substrate with a thickness of about 0.05 mm to 0.2 mm can be used for the substrate 5a.

An epoxy resin-based thermosetting resin member or silicone-based elastomer member can be used for the sealing resin member 5b.

When the sealing resin member 5b is the silicone-based elastomer member, the elastomer part can alleviate an external stress because the elastomer part functions as a cushion. This also improves the reliability against a bending after product assembling and against a drop.

The thickness of the sealing resin member 5b is not limited to that shown in the figure. The warp reducing member 5 can also include only the substrate 5a without using the sealing resin member 5b.

When the size of the electrode 10 is about 0.2 mm or larger, the warp reducing member can be created easily, which is a dimension of an electrode of a 0.5 mm pitch BGA package. A dimension L of a frame of the warp reducing member 5 (see FIG. 1) can be preset to 0.5 mm or larger. The dimension of the electrode 10 and the number of electrodes 10 can be preset to arbitrary values according to the size of the warp reducing member 5, without being limited to a specific value.

By mounting the warp reducing member 5 a temperature distribution on a predetermined areas of the substrate 1 becomes uniform, which makes it possible to reduce a local warp of the substrate 1. Therefore, the part 2 can be mounted on the substrate 1 with an excellent quality, and as a result, a high reliability can be obtained.

Furthermore, a structure optimum for the warp behavior of the substrate 1 or the part 2 can be selected by controlling the warp behavior of the warp reducing member 5 according to a design content including a thickness of the substrate 5a and a density of the electrodes 10a, a selection of a material and a thickness of the sealing resin member 5b, and a combination of the above conditions.

A solder can be used as a bonding material 6 to bond the warp reducing member 5 to the substrate 1. It is preferable for the bonding material 6 to have a melting point lower than that of the solder joint 4 for bonding the part 2. It is also preferable that the warp reducing member 5 can be removed from the substrate 1 when needed.

When the warp reducing member 5 is bonded to the substrate 1 by soldering, the warp reducing member 5 can removed from the substrate 1 by heating the substrate 1 to melt the solder. If the melting point of the bonding material 6 is lower than that of the solder joint 4, the warp reducing member 5 can be removed by melting the bonding material 6. In this case, by employing the bonding material 6 having the melting point lower than that of the solder joint 4, the bonding state of the part 2 to the substrate 1 through the solder joint 4 is not affected by the heating of the substrate 1 to remove the warp reducing member 5.

As a specific structure for soldering the warp reducing member 5 to the substrate 1, Sn-58Bi with a melting point of 138° C. is preferably formed in advance on the electrode 10 of the warp reducing member 5 as the solder ball 11 (see FIG. 3).

It is known that lead-free solders used in recent years have a relatively high melting point. If a solder paste 41 (lead-free) such as Sn-3Ag-0.5Cu with a melting point of 217° C. is used for soldering the other parts 3 to the substrate 1, when the warp reducing member 5 is mounted in the process in which the other parts 3 is mounted, the warp reducing member 5 is also mounted on the substrate 1 by lead-free soldering.

Due to the high melting point of the lead-free solder, it is difficult to remove the warp reducing member 5 without affecting the part 2 mounted on the substrate 1 or the solder joint 4 for bonding the part 2 to the substrate 1.

If the solder ball 11 such as Sn-58Bi is formed in advance on the warp reducing member 5, however, the solder melting point after soldering can be kept low (at 160° C. or

below, for example) even when the solder paste 41 is used for soldering with the solder ball 11.

If the diameter of the solder ball 11 on the warp reducing member 5 is 0.5 mm, the amount of lead-free solder to be supplied can be limited so that the mixed amount is 10% or less with respect to the solder ball 11. Accordingly, the melting point of the bonding material 6 can be kept low.

There may be a need to remove the warp reducing member 5 after the part 2 has been mounted. Even in this case, since the temperature for heating the substrate 1 can be kept low, the warp reducing member 5 can be removed from the substrate 1 without causing thermal damage to the part 2 and the other parts 3.

FIG. 4 is a cross section of the substrate for illustrating a process for supplying the solder paste 41 to the back of the substrate 1. FIG. 5 is a cross section of the substrate for illustrating a process for soldering the other parts 3 to the back surface of the substrate 1. FIG. 6 is a cross section of the substrate for illustrating another process for supplying the solder paste 41 to the back of the substrate 1. FIG. 7 is a cross section of the substrate for illustrating another process for soldering the other parts 3 to the back surface of the substrate 1. The front surface of the substrate 1 is the surface on which the part 2 is mounted.

The solder paste 41 is supplied to predetermine portions (positions at which the other parts 3 and the warp reducing member 5 are to be mounted) on the back surface of the substrate 1, as shown in FIG. 4. The warp reducing member 5 and the other parts 3 are then placed on the back surface of the substrate 1 and soldered to the substrate 1, as shown in FIG. 5. The solder ball 11 on the warp reducing member 5 and the solder paste 41 on the substrate 1 are combined into a single bonding material 6 (see FIG. 6).

The substrate 1 is then reversed as shown in FIG. 6, and the solder paste 41 is supplied to the positions on the front surface of the substrate 1 at which the part 2 and the other parts 3 are to be mounted. As shown in FIG. 7, the part 2 and the other parts 3 are then placed and soldered at the positions corresponding to the warp reducing member 5 on the front surface of the substrate 1.

As a result of providing the warp reducing member 5, the thermal distributions on the predetermined portion on the front surface of the substrate 1 and the corresponding portion on the back surface become uniform. A local warp, particularly a warp near the outer periphery, is thereby reduced.

The solder paste 41 bonds the part 2 or the other parts 3 to the substrate 1, and becomes the solder joint 4 shown in FIG. 1. According to the above processes, a structure for reducing warp of the substrate 1 is created.

As described above, the method of reducing the warp of the substrate 1 is carried out in an ordinary process for mounting parts on both surfaces of a substrate, without any special material and process. The warp of the substrate 1 can be thus reduced quickly at a low cost.

The solderability and reliability of the part 2 can also be increased without adding any special process if the warp reducing member 5 is created with warp behavior of the substrate 1 or the part 2 taken into consideration and soldered to the back surface of the substrate 1 in advance.

According to first embodiment, the warp of the substrate 1 is reduced during the mounting of the part 2 and the other parts 3 to increase the quality of part mounting, without adding a new process to an ordinary process for mounting the parts. The first embodiment also contributes to thinning the substrate 1 by allocating part mounting areas and increasing packaging density. Reliability after part mounting can also be increased.

According to the first embodiment, to mount the warp reducing member 5 and the other parts 3 on the substrate 1 in the same process, the solder balls 11 are formed on the warp reducing member 5 in advance, and the warp reducing member 5 is placed on the solder paste 41 supplied to the substrate 1, and soldered.

If it is acceptable, for example, to mount the other parts 3 and the warp reducing member 5 in different processes, however, the other parts 3 may be first mounted on the substrate 1 by use of the solder paste 41 and then the warp reducing member 5 may be mounted on the substrate 1 by use of a solder material having a different (lower) melting point. In this case, in addition to the process for supplying the solder paste 41 to the substrate 1, another process is required to supply the solder material with the different melting point to the substrate 1, so that the warp reducing member 5 is placed on the solder material, and soldered.

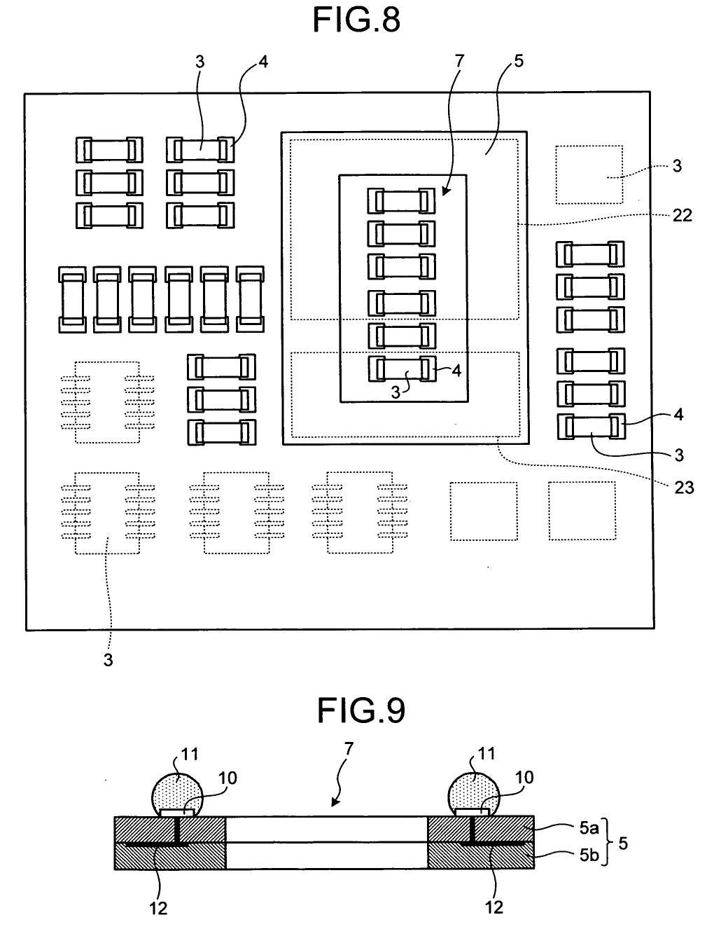

FIG. 8 is a plan view of a structure for reducing a warp of a substrate, according to a second embodiment of the present invention. The dotted lines in FIG. 8 indicate parts mounted on the front surface of the substrate 1, and the solid lines indicate parts mounted on the back surface of the substrate 1. The second embodiment provides a structure for reducing the warp of the substrate 1 in a plurality of part areas by use of the warp reducing member 5, as shown in FIG. 8.

In FIG. 8, reference numerals 22 and 23 indicate the outside shapes of a first part and second part, respectively, mounted on the front surface of the substrate 1. The warp reducing member 5 is formed with almost the same size as the areas occupied by the outer shapes 22, 23 of two parts. The warp reducing member 5 is mounted on the back surface of the substrate 1.

The warp reducing member 5 has a structure similar to the structure shown in the first embodiment, so it can be mounted on the substrate 1 by a process similar to the process in the first embodiment. According to the second embodiment, a structure for reducing the warp of the substrate 1 in two part areas is described, but the structure is not limited to two areas. The warp of the substrate 1 can also be reduced by forming the warp reducing member 5 in correspondence to the outside shapes of three or more part areas.

The substrate warp reducing structure according to the second embodiment provides the same effect as in the first embodiment, and also reduces the warp of the substrate 1 in a plurality of part areas by use of the warp reducing member 5.

FIG. 9 is a cross section of a substrate warp reducing structure according to a third embodiment of the present invention. According to the third embodiment, a wiring 12 is formed on the substrate 5a of the warp reducing member 5, to configure the warp reducing member 5 as a printed circuit board. Accordingly, wiring that cannot be processed on the substrate 1 can be formed and wiring for improving electrical characteristics can be added.

Specifically, it becomes possible to supplement part of wiring on the substrate 1 on which wires are difficult to route. Then, multilayer wiring and fine wiring on the substrate 1 as well as an increase of accompanying cost can be suppressed. Other structures are nearly the same as in the first embodiment, and duplicate description will be omitted.

The warp reducing member 5 according to the third embodiment provides the same effect as in the first embodiment. The warp reducing member 5 also suppresses multilayer wiring and fine wiring that extend over the entire substrate 1, thereby making the substrate 1 thinner and reducing the cost.

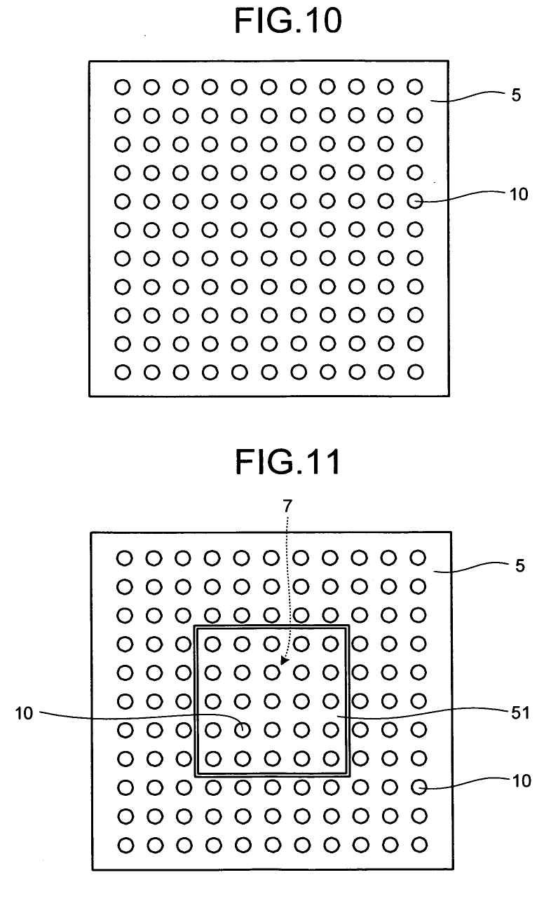

FIG. 10 is a plan view of a warp reducing member according to a fourth embodiment of the present invention. According to the fourth embodiment, a plurality of electrodes 10 are provided at a preset pitch, which are used to attach solder over the entire warp reducing member 5.

Solder balls (each of which equivalent to the solder ball 11 shown in FIG. 3 according to the first embodiment) are provided for the electrodes 10, according to the area where the warp of the substrate 1 needs to be reduced. The warp reducing member 5 is then mounted on the substrate 1 in nearly the same process as in the first embodiment.

The warp reducing member 5 according to fourth embodiment enables the warp reducing member 5 to be mounted in a common process.

FIG. 11 is a plan view of a warp reducing member according to a fifth embodiment of the present invention. Pluralities of electrodes 10 are provided at a preset pitch, which are used to attach solder over the entire warp reducing member 5. The warp reducing member 5 also has the opening 7.

A warp reducing member 51 has a shape that matches the shape of the opening 7 in the warp reducing member 5, and lacks an opening. The warp reducing member 51 is detachably provided in the opening 7.

The opening 7 may be used in some mounting state of the other parts 3 on the substrate 1, in which case the warp reducing member 5 can be mounted on the substrate 1 with the warp reducing member 51 removed from the warp reducing member 5.

If the opening 7 is not used, the warp reducing members 5, 51 can be mounted on the substrate 1 with the warp reducing members 5, 51 combined.

When the warp reducing members 5, 51 according to the fifth embodiment are mounted on the substrate 1, it can be determined easily whether to use the opening 7 according to the mounting state of the other parts 3 on the substrate 1. Therefore, the warp reducing members 5, 51 can be mounted flexibly according to the part mounting state of the substrate 1.

According to the fifth embodiment, the warp reducing member 5 with the opening 7 has been combined with the warp reducing member 51 without an opening. However, the embodiment is not limited to this combination; a combination of three or more warp reducing members having an opening, for example, is allowed.

After the part 2 is mounted on the substrate 1 for which warp has been reduced by the warp reducing member 5, the warp reducing member 5 is not necessarily left mounted on the substrate 1.

A sixth embodiment of the present invention provides processes for removing the substrate 1 from the warp reducing member 5. The sixth embodiment is performed in response to a request for making apparatus small, lightweight, and particularly thin.

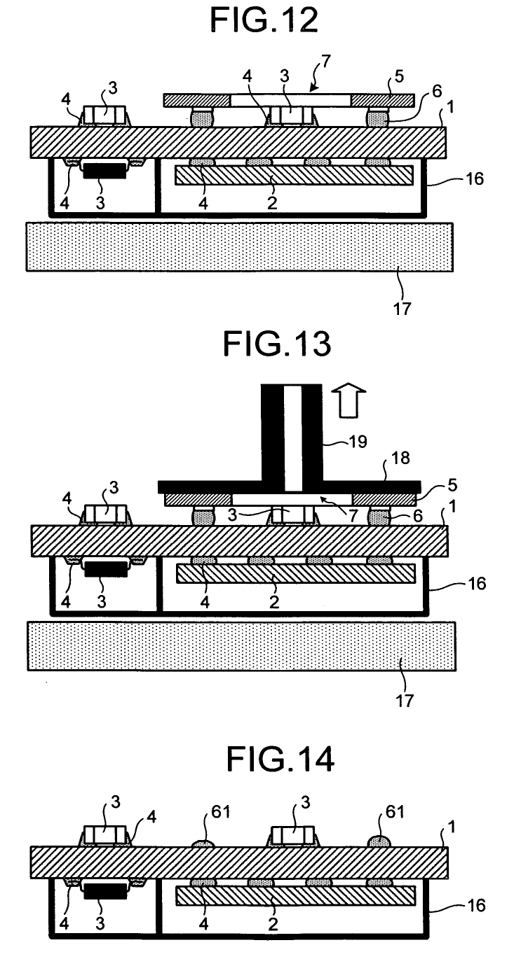

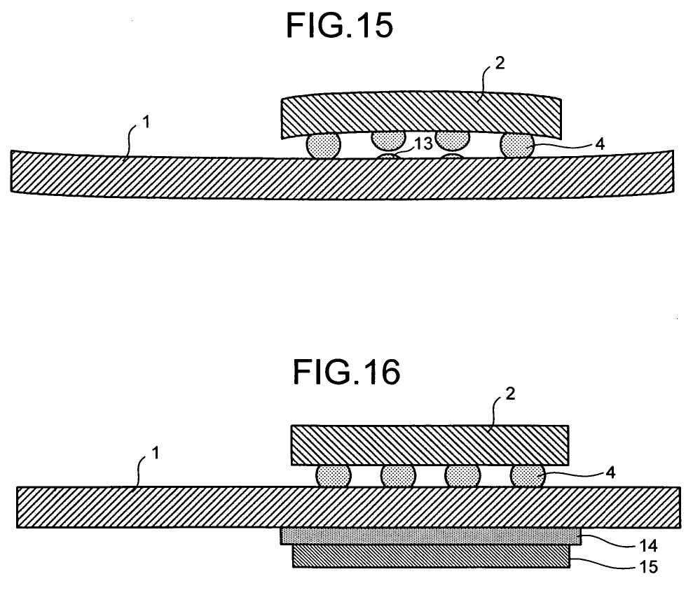

FIG. 12 is a cross section of the substrate for illustrating a process for removing a warp reducing member, according to the sixth embodiment. In this process, the entire substrate 1 is heated. FIG. 13 is a cross section of the substrate for illustrating a process for removing a warp reducing member 5. FIG. 14 is a cross section of the substrate for illustrating a process for leveling the solder.

In the heating process, the substrate 1 is secured to a jig 16 or another tool as shown in FIG. 12, and the entire substrate 1 is heated to about 100° C. with a heater 17 or the like.

In the process for removing the warp reducing member 5, it is heated by means of an ordinary part removing tool 19 or the like, the end 18 of which can be set to about 170° C., and removed from the substrate 1, as shown in FIG. 13.

To prevent the part 2, the other parts 3, and the solder joints 4 from being thermally damaged, the bonding material 6 for bonding the warp reducing member 5 is made of a material with a melting point lower than that of the solder joint 4.

In the leveling process, after the warp reducing member 5 has been removed from the substrate 1, solder residues 61 having different amounts of solder or shapes are equalized or flattened by using a solder iron or another tool, as shown in FIG. 14. However, the leveling process can be eliminated, as necessary. In this case, the solder residues 61 remain on the substrate 1. Even after the process for equalizing or flattening has been performed, the solder residues 61 remain a little on the substrate 1.

It is also possible to remove only the bonding material 6 of the solder by melting it. To do this, the electrode 10 for attaching the solder for the warp reducing member 5 is formed by a continuous copper foil or the like. The electrode 10 is then locally heated by connecting part of the copper foil to a heat source.

If the electrode 10 on the warp reducing member 5 is larger (has a larger area) than the corresponding electrode on the substrate 1, the heat is transferred further easily. Furthermore, the melted bonding material 6 tends to be attracted toward the warp reducing member 5 due to the surface tension of the solder when the warp reducing member is removed. This is also advantageous for the leveling process.

After the leveling has been performed for the solder residue 61 of each bonding material 6 that is left on the electrode and then a new solder ball is formed, the removed warp reducing member 5 can be reused.

As described above, the removing process for the warp reducing member 5 according to the sixth embodiment can remove the warp reducing member 5 easily from the substrate 1 without causing thermal damage to the part 2, the other parts 3, and the solder joints 4 thereof. This contributes to achieving compact, lightweight, and particularly thin apparatus.

According to the present invention, electronic parts can be mounted superiorly on the substrate, and thereby reliability is obtained.

Furthermore, according to the present invention, it is possible to achieve high-density packaging by placing prescribed electronic parts in an opening of a warp reducing member and mounting them on the substrate.

Moreover, according to the present invention, the local warp can be further reduced.

Furthermore, according to the present invention, it is possible to improve the reliability of electrical connection to a bonding material.

Moreover, according to the present invention, multilayer wiring and fine wiring as well as accompanying cost increase can be suppressed.

Furthermore, according to the present invention, it is possible to selectively mount a warp reducing member with an opening and a warp reducing member without an opening according to the mounting state of the electronic parts on the substrate in order to adapt flexibly to the part mounting state of the substrate.

Moreover, according to the present invention, it is possible to reduce substrate warp quickly with a low cost.

Furthermore, according to the present invention, it is possible to remove the warp reducing member easily from the substrate when needed, which contributes to achieving compact, lightweight, and particularly thin apparatus.

Moreover, according to the present invention, it is possible to perform leveling for residues of the bonding material and to form a new bonding material such as a solder ball at an appropriate place so that the warp reducing member can be reused.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A structure for reducing a warp of a substrate on which a plurality of electronic parts are mounted, the structure comprising:
a warp reducing member configured to be bonded to an area on one surface of the substrate corresponding to other side of an electronic part for which the warp is to be reduced with respect to the substrate, wherein
an external size of the warp reducing member is substantially same as a size of each of the electronic parts or large enough to include multiple electronic parts, and
the warp reducing member is bonded to the substrate with a bonding material having a melting point lower than that of other bonding material that electrically connects the electronic parts to the substrate.

2. The structure according to claim 1, wherein
the warp reducing member includes an opening through which the one surface of the substrate can be accessed from outside.

3. The structure according to claim 1, wherein
the warp reducing member is formed with any one of a glass epoxy substrate, a complex of a glass epoxy substrate or a polyimide substrate and an epoxy resin member, and a complex of a glass epoxy substrate or a polyimide substrate and a silicone-based elastomer member.

4. The structure according to claim 1, wherein
the warp reducing member includes an electrode for bonding.

5. The structure according to claim 4, wherein
the warp reducing member further includes a wiring for electrically connecting to the substrate, and
an electric process of the substrate or the electronic parts is performed through the wiring.

6. The structure according to claim 4, wherein
the electrode includes a solder ball.

7. The structure according to claim 1, wherein
a coefficient of thermal expansion of the warp reducing member is substantially same as that of the electronic parts.

8. The structure according to claim 2, wherein
a small-size warp reducing member that matches a shape of the opening is detachably provided within the opening.

9. The structure according to claim 1, wherein
the electronic parts are leadless parts.

10. A method of reducing a warp of a substrate on which a plurality of electronic parts are mounted, the method comprising:
bonding a warp reducing member to an area on one surface of the substrate corresponding to other side of a first electronic part for which the warp is to be reduced with respect to the substrate; and
mounting the first electronic part on other surface of the substrate corresponding to the area on which the warp reducing member is bonded, wherein
the bonding is performed at a same process as mounting a second electronic part on the substrate.

11. The method according to claim 10, wherein
the warp reducing member includes an opening through which the one surface of the substrate can be accessed from outside, and
the mounting includes mounting a second electronic part on the one surface of the substrate through the opening when bonding the warp reducing member to the area on the one surface of the substrate before mounting the first electronic part on the other surface of the substrate.

12. The method according to claim 10, further comprising:
heating the entire substrate on which the electronic parts are mounted and the warp reducing member is bonded up to a predetermined temperature; and
removing the warp reducing member from the substrate by further heating a joint portion of the warp reducing member and the substrate to melt the bonding material.

13. The method according to claim 12, further comprising:
leveling the bonding material by further melting a residual of the bonding material formed on the substrate after the removing.

14. A wiring board on which a plurality of electronic parts are mounted, the wiring board comprising:
an electronic part that is mounted in a first area on a first surface of the wiring board with a first bonding material; and
a warp reducing member that is bonded to a second area on a second surface of the wiring board with a second bonding material, the second area corresponding to the first area.

15. The wiring board according to claim 14, wherein
both the first bonding material and the second bonding material are solders, and
a melting point of the second bonding material is lower than a melting point of the first bonding material.

16. The wiring board according to claim 14, wherein
the warp reducing member includes a third bonding material,
the second bonding material is a melted mixture of the first bonding material and the third bonding material.

17. The wiring board according to claim 16, wherein
a melting point of the third bonding material is lower than a melting point of the first bonding material.

18. A wiring board on which a plurality of electronic parts are mounted, the wiring board comprising:
an electronic part that is mounted on a first surface of the wiring board with a first bonding material; and
a warp reducing member that is temporarily bonded on a second surface of the wiring board with a second bonding material.

19. A method of manufacturing a wiring board on which a plurality of electronic parts are mounted, the method comprising:
mounting an electronic part on a first surface of the wiring board with a first bonding material; and
bonding a warp reducing member to a second surface of the wiring board with a second bonding material.

20. The method according to claim 19, wherein
the bonding includes
forming a third bonding material on the warp reducing member;
forming the first bonding material on the wiring board; and
bonding the warp reducing member to the wiring board in such a manner that the first bonding material and the third bonding material are brought into contact with each other.

21. The method according to claim 19, wherein
the bonding includes
forming the second bonding material on the second surface of the wiring board; and
bonding the warp reducing member to the second surface of the wiring board.

22. The method according to claim 19, further comprising:
heating the wiring board on which the warp reducing member is bonded; and
removing the warp reducing member from the heated wiring board.

23. The method according to claim 19, wherein
a melting point of the second bonding material is lower than a melting point of the first bonding material.
